(19) United States
(12) Patent Application Publication
(10) Pub. No.: US 2025/0323153 A1
(43) Pub. Date: Oct. 16, 2025

(54) MULTI-PART BACKSIDE CONTACTS FOR STACKED TRANSISTORS

(71) Applicant: INTERNATIONAL BUSINESS MACHINES CORPORATION, Armonk, NY (US)

(72) Inventors: Ruilong Xie, Niskayuna, NY (US); Chen Zhang, Santa Clara, CA (US); Shirin Akter, Irvine, CA (US); Huimei Zhou, Albany, NY (US)

(21) Appl. No.: 18/632,675

(22) Filed: Apr. 11, 2024

(51) Int. Cl. H01L 23/528; H01L 23/522; H01L 27/06; H01L 27/088

(52) U.S. Cl. CPC H01L 23/5283; H01L 23/5226; H10D 84/83; H10D 88/00

(57) ABSTRACT

Semiconductor devices include a top field effect transistor (FET) and a bottom FET. A first conductive via is in electrical connection with a first conductive interconnect beneath the bottom FET. A second conductive via is in electrical connection with the first conductive via. A backside top FET contact is in electrical connection with the top FET and with a side surface of the second conductive via.

### BACKGROUND

The present invention generally relates to semiconductor device fabrication and, more particularly, to stacked field effect transistors (FETs).

When forming contacts to stacked FETs in a device, the close spacing between FETs can result in electrical shorts that render the device inoperable. This is particularly true in devices that make use of a backside power distribution network, as vias to the backside power distribution network may run between adjacent FETs. In such devices, the contact to the top FET of the stacked FETs may need to extend laterally to reach to the backside via, putting it close to contacts of the adjacent stacked FETs. This can result in tip-to-tip shorting between the conductive interconnects, reducing device yield.

### SUMMARY

A semiconductor device includes a top field effect transistor (FET) and a bottom FET. A first conductive via is in electrical connection with a first conductive interconnect beneath the bottom FET. A second conductive via is in electrical connection with the first conductive via. A backside top FET contact is in electrical connection with the top FET and with a side surface of the second conductive via.

A semiconductor device includes a first stacked pair of FETs and second stacked pair of FETs. The first stacked pair of FETs includes a first top FET, a first bottom FET, a first conductive via in electrical connection with a first conductive interconnect under the first bottom FET, a second conductive via in electrical connection with the first conductive via, and a backside top FET contact in electrical connection with the first top FET and with a side surface of the second conductive via. The second stacked pair of FETs includes a second top FET, a second bottom FET, a frontside bottom FET contact in electrical connection to a second conductive interconnect above the second top FET, a third via in electrical connection to the frontside bottom FET contact, a bottom FET contact in electrical connection to the third via and to the second bottom FET.

A semiconductor device includes a buried power distribution layer that includes a first conductive interconnect, a back-end-of-line (BEOL) layer that includes a second conductive interconnect, a first stacked pair of FETs between the buried power distribution layer and the BEOL layer, and a second stacked pair of FETs between the buried power distribution layer and the BEOL layer. The first stacked pair of FETs includes a first top FET, a first bottom FET, a first conductive via in electrical connection with the first conductive interconnect, a second conductive via in electrical connection with the first conductive via, and a backside top FET contact in electrical connection with the first top FET and with a side surface of the second conductive via. The second stacked pair of FETs includes a second top FET, a second bottom FET, a frontside bottom FET contact in electrical connection to the second conductive interconnect, a third via in electrical connection to the frontside bottom FET contact, and a bottom FET contact in electrical connection to the third via and to the second bottom FET.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of electrical contacts to stacked field effect transistors (FETs), showing a set of stacked FETs that each include a top FET and a bottom FET, in accordance with an embodiment of the present invention;

FIG. 2 is a cross-sectional view of a step in the fabrication of electrical contacts to stacked FETs, showing the formation of a first backside via and bottom FET contacts, in accordance with an embodiment of the present invention;

FIG. 3 is a cross-sectional view of a step in the fabrication of electrical contacts to stacked FETs, showing the formation of second vias on the first backside via and the bottom FET contacts, in accordance with an embodiment of the present invention;

FIG. 4 is a cross-sectional view of a step in the fabrication of electrical contacts to stacked FETs, showing the formation of openings that expose a top FET and a side surface of the second via over the first backside via, in accordance with an embodiment of the present invention;

FIG. 5 is a cross-sectional view of a step in the fabrication of electrical contacts to stacked FETs, showing the deposition of conductive material in the openings to form an connection between the first backside via and the exposed top FET, in accordance with an embodiment of the present invention;

FIG. 6 is a cross-sectional view of a step in the fabrication of electrical contacts to stacked FETs, showing the of a back-end-of-line layer over the stacked FETs, in accordance with an embodiment of the present invention;

FIG. 7 is a cross-sectional view of a step in the fabrication of electrical contacts to stacked FETs, showing the removal of a substrate layer to expose the first backside via, in accordance with an embodiment of the present invention;

FIG. 8 is a cross-sectional view of a step in the fabrication of electrical contacts to stacked FETs, showing the replacement of a sacrificial structure under a bottom FET with a conductive contact, in accordance with an embodiment of the present invention;

FIG. 9 is a cross-sectional view of a step in the fabrication of electrical contacts to stacked FETs, showing the formation of a backside power distribution network that connects to the first backside via and the contact to the bottom FET, in accordance with an embodiment of the present invention;

FIG. 10 is a block/flow diagram of a method for forming a semiconductor device with stacked FETs and a multi-part backside contact, in accordance with an embodiment of the present invention.

### DETAILED DESCRIPTION

Stacked field effect transistors (FETs) may be formed in devices with backside power distribution. In such devices, there may be power-carrying lines on a front side of the device and on a back side of the device, with contacts that reach through the device to make contact with a top or bottom FET of a stacked pair of FETs, as appropriate. Because contacts to the top FET from the backside power distribution may travel between adjacent stacks of FETs, the formation of the via and the contact has implications for tip-to-tip shorts between the contacts of adjacent stacks and further has implications for how the contact for the top device connects to the via from the backside power distribution.

Some embodiments of a device with stacked FETs may make use of a multi-part via that extends from the back side of the device and reaches to a height above a top FET in a pair of stacked FETs. A top contact between the via and the top FET may then be formed in a manner that makes an electrical connection between the top contact and the via along a sidewall of the via. This makes it possible to reduce the lateral reach of the top contact, thereby decreasing the likelihood of a short between the top contact and a contact for an adjacent FET. The sidewall contact furthermore provides a large surface area for the electrical connection between the top contact and the via, thereby reducing electrical resistance along this interface. Thus, rather than having to reach laterally to make a relatively small contact interface with the top surface of the via, the contact to the top FET may leave additional space between it and neighboring interconnects, while ensuring a large conductive interface area to reduce resistance.

Referring now to FIG. 1, a cross-sectional view of a step in the fabrication of a semiconductor device is shown. This cross-sectional view is taken through a set of adjacent stacked FETs, in particular showing a source/drain region of those FETs. A base substrate 102 is shown with an etch stop layer 104 separating the base substrate 102 from a device layer 106. The multi-layer substrate, including the base substrate 102, the etch stop layer, and the device layer 106, makes it possible to subsequently process the substrate to expose an back side of the device to make electrical contact with those structures from the backside of the device.

The base substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

The etch stop layer 104 may be formed from any material having an appropriate etch selectivity with respect to the material of the base substrate 102. In an example where the base substrate 102 is silicon, the etch stop layer 104 may be formed from silicon germanium. The device layer 106 may similarly be formed from a material that has an appropriate etch selectivity with respect to the material of the etch stop layer, such as silicon.

Shallow trench isolation (STI) structures 108 are formed in the device layer 106, for example by an anisotropic etch that forms trenches, followed by a deposition to fill the trenches with an appropriate insulator material, such as silicon dioxide. Excess insulator material may be removed by a chemical mechanical planarization (CMP) process that stops on the device layer 106. CMP is performed using, e.g., a chemical or granular slurry and mechanical force to gradually remove upper layers of the device. The slurry may be formulated to be unable to dissolve, for example, the material of the device layer 106, resulting in the CMP process's inability to proceed any farther than that layer.

FETs may be formed on the device layer 106, for example by forming nanosheet channels with a gate stack. The structural details of the channel(s), the gate stack, and any insulating layers are not material to the present description, and it should be understood that any appropriate FET structure may be used. Each stacked pair of FETs may include a top FET 114 and a bottom FET 112. In some cases, a bottom FET 112 may be separated from the underlying device layer 106 by an isolation layer 110 that is formed from an appropriate insulating material, such as silicon nitride. In other cases, a bottom FET 112 may be in contact with a bottom sacrificial structure 109, which may formed by etching away a portion of the device layer 106 and replacing it with a sacrificial material having an appropriate etch selectivity, such as silicon germanium. When the source/drain structures are grown from the channels of the respective FETs, the source/drain structure of such a bottom FET 112 may grow to contact the sacrificial structure 109.

An interlayer dielectric 116 is formed around the top FETs 114 and the bottom FETs 112. The interlayer dielectric 116 may be formed by any appropriate dielectric material, such as silicon dioxide in a flowable chemical vapor deposition (CVD) process. The interlayer dielectric 116 may be formed to a height above the top FETs 114, thereby covering the top FETs 114. The term “height” as used herein refers to a height above a backside of the device.

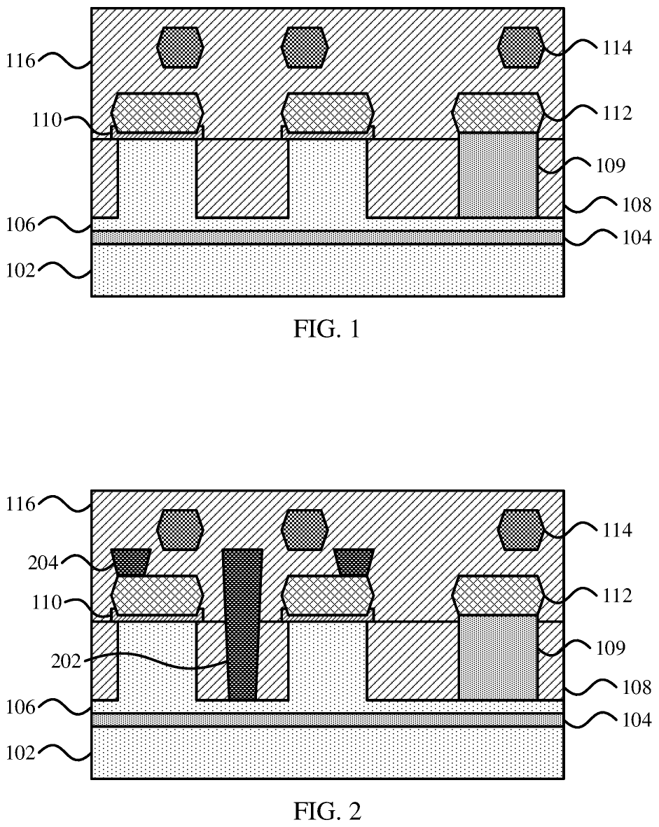

Referring now to FIG. 2, a cross-sectional view of a step in the fabrication of a semiconductor device is shown. A first backside via 202 is formed through the STI structure 108 to reach to the device layer 106. The first backside via may then be covered again by dielectric material to provide electrical insulation.

The first backside via 202 may be formed by, e.g., etching through the interlayer dielectric 116 and the STI structure 108 using a photolithographic mask and an anisotropic etch, followed by a deposition of conductive material, followed by CMP and recess. This recess lowers the top surface of the conductive material to or below the level of the top FETs 114, as shown. The remaining etched area may then be refilled with dielectric material.

Bottom FET contacts 204 may be formed by a similar process. The first backside via 202 and the bottom FET contacts 204 may be formed to a height that reaches to a same height as a bottom surface of the top FETs 114, or to a height between the top FETs 114 and the bottom FETs 112.

The first backside via 202 may be patterned using a photolithographic pattern. The pattern may be produced by applying a photoresist to the surface to be etched. The photoresist may be exposed to a pattern of radiation that defines the locations where the first backside via 202 and the bottom FET contacts 204 are to be formed. The pattern may be developed into the photoresist utilizing a resist developer, for example creating a mask. Once the patterning of the photoresist is completed, the sections covered by the photoresist are protected while the exposed regions are removed using a selective etching process that removes the unprotected regions.

Reactive ion etching (RIE) is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. This has the effect of anisotropically etching the material, for example the silicon dioxide of the interlayer dielectric 116 and the STI structure 108. The RIE may furthermore be made selective to the material that is to be removed. As used herein, the term “selective” in reference to a material removal process denotes that the rate of material removal for a first material is greater than the rate of removal for at least another material of the structure to which the material removal process is being applied. Thus the etch may be formulated to stop on the material of the device layer 106.

The conductive material of the first backside via 202 and the bottom FET contacts 204 may be formed from any appropriate conductive metal such as, e.g., a silicide layer (e.g., titanium, nickel, nickel-platinum), an adhesion metal layer such as titanium nitride, or a conductive metal, such as tungsten, nickel, titanium, molybdenum, tantalum, copper, platinum, silver, gold, ruthenium, iridium, rhenium, rhodium, cobalt, and alloys thereof. The conductive material may alternatively include a doped semiconductor material such as, e.g., doped polysilicon.

The conductive material may be formed by any appropriate deposition process, such as CVD, physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 3, a cross-sectional view of a step in the fabrication of a semiconductor device is shown. Second vias 302 are formed through the interlayer dielectric 116, for example using a photolithographic etch and deposition of conductive material. The second vias 302 may make contact with the first backside via 202 and the bottom FET contacts 204. After trenches are formed in the interlayer dielectric 116, and after conductive material is deposited in the trenches, a CMP process may be performed to remove any excess conductive material from the top surface of the interlayer dielectric 116.

The first backside via 202 and the second vias 302 are shown as being tapered, with a larger width at the front side of the structures and a smaller width at the back side of the structures. This is a result of the anisotropic etch process, which tends to produce a sloped sidewall in an etched structure. As a result, the second vias 302 are physically distinguishable from the first backside via 202, even when formed from a same conductive material, due to the stepped profile that results from matching the narrow bottom of the second via 302 to the wider top of the first backside via 202.

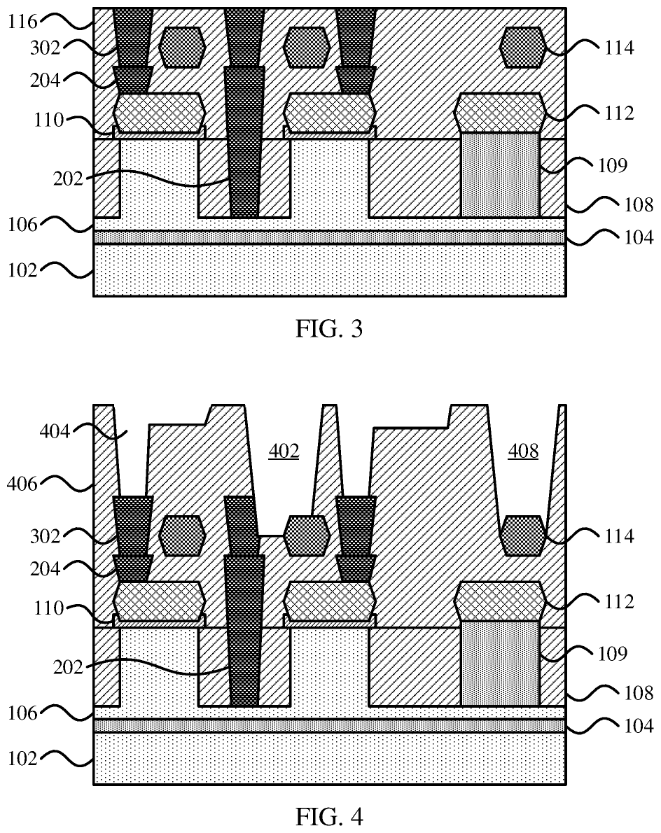

Referring now to FIG. 4, a cross-sectional view of a step in the fabrication of a semiconductor device is shown. Additional dielectric material is deposited by any appropriate process to extend the interlayer dielectric 406 to a height above the second vias 302. Openings are formed in the interlayer dielectric, for example by forming a photolithographic mask and by an anisotropic etch. The openings may include an opening 402 that exposes a side surface of the second via 302 over the first backside via 202. The openings may further include openings 404 for frontside bottom FET contacts that make electrical connection to the bottom FETs 112 through the bottom FET contacts 204. Also shown is an opening 408 for a frontside top FET contact. Some material may be removed from exposed portions of the second vias 302, for example as shown in opening 402, using a respective selective anisotropic etch.

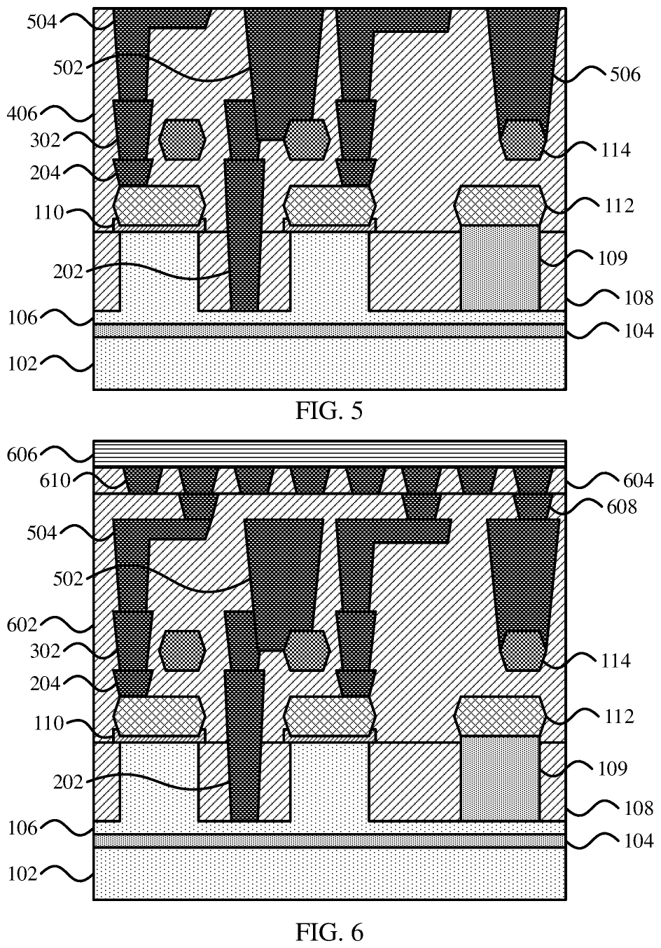

Referring now to FIG. 5, a cross-sectional view of a step in the fabrication of a semiconductor device is shown. The openings 402/404 are filled with conductive material, creating backside top FET contacts 502, frontside bottom FET contacts 504, and frontside top FET contacts 506.

Referring now to FIG. 6, a cross-sectional view of a step in the fabrication of a semiconductor device is shown. Additional dielectric material is deposited over the backside top FET contacts 502, the frontside bottom FET contacts 504, and the frontside top FET contacts 506 to form interlayer dielectric 602. Conductive vias 608 are formed through the interlayer dielectric, for example by a photolithographic patterning and etch process, followed by deposition of conductive material and a CMP process.

A layer 604 of metal interconnects 610 may be formed over the interlayer dielectric 602, for example including deposition of an appropriate dielectric material, followed by photolithographic patterning and etching of trenches in the dielectric material, followed by deposition of conductive material. Additional back-end-of-line (BEOL) layers 606 may similarly be formed over the layer 604 of metal interconnects 610, providing power and signal communication as appropriate to the top and bottom FETs.

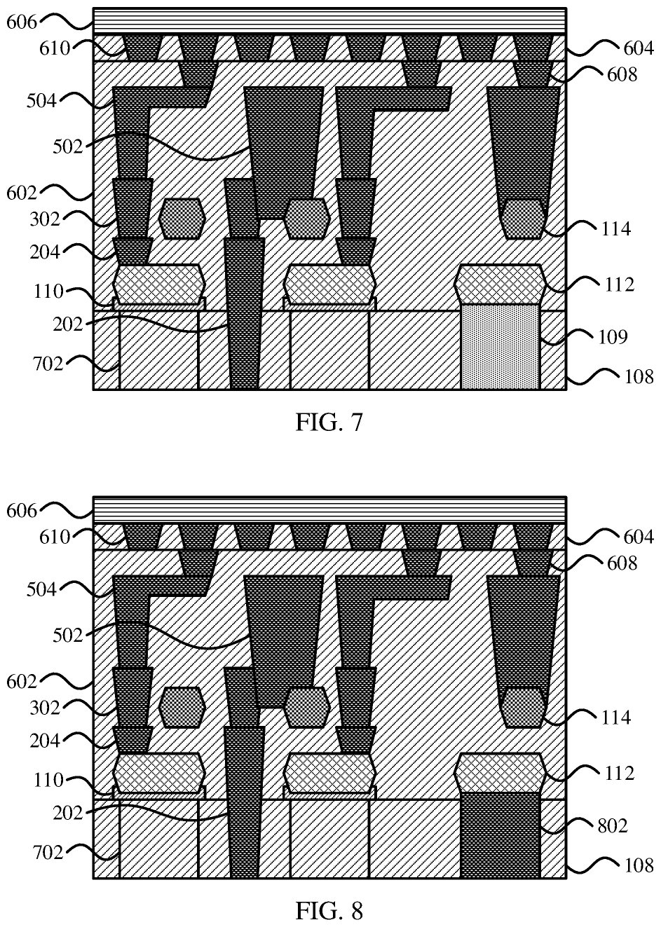

Referring now to FIG. 7, a cross-sectional view of a step in the fabrication of a semiconductor device is shown. A carrier wafer (not shown) is bonded to the BEOL layers 606, followed by wafer flip. The base substrate 102 is removed, for example using any appropriately selective etch. The etch stop layer 104 is then removed as well. A selective etch may then be used to remove the remaining portions of the device layer 106, for example using an etch that preserves the exposed surfaces of the STI structures 108, the sacrificial structure 109, and the first backside via 202. The openings left between the STI structures 108, left by the removal of the device layer 106, are filled by a deposition dielectric material 702, which may then be polished back to the level of the sacrificial structure 109 using a CMP process.

Referring now to FIG. 8, a cross-sectional view of a step in the fabrication of a semiconductor device is shown. The sacrificial structure 109 may be selectively etched away to expose a surface of a bottom FET 112. The opening left by removal of the sacrificial structure 109 may then be filled by deposition of a conductive material, following by a CMP process, to form backside bottom FET contact 802.

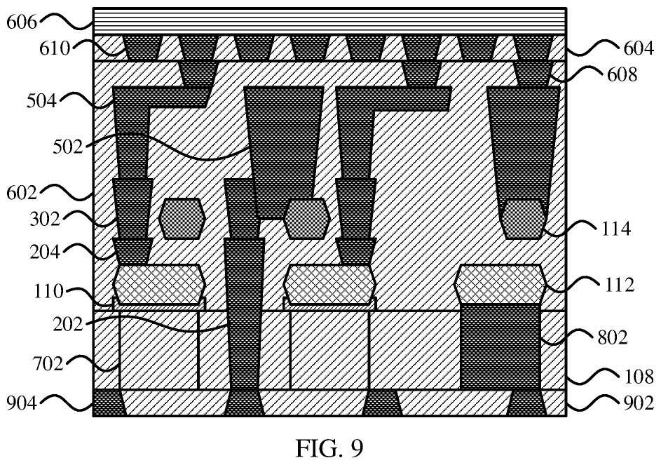

Referring now to FIG. 9, a cross-sectional view of a step in the fabrication of a semiconductor device is shown. A backside power distribution layer 902 is formed with backside power rails 904 or other conductive interconnects, for example by depositing a layer of dielectric material, forming trenches using a photolithographic patterning and etch, depositing conductive material to fill the trenches, and performing a CMP to expose the dielectric material again. The backside power rails 904 may align with the first backside via 202 and the backside bottom FET contact 802 to provide electrical connections thereto. Additional backside power distribution layers may be formed on the backside power distribution layer 902 with backside power rails 904.

The first backside via 202 thereby connects the backside power rails 904 to a top FET 114 by way of second via 302 and backside top FET contact 502. Because the backside top FET contact 502 makes electrical contact with the second via 302 along a side surface of the second via 302, a relatively large interface area is provided to lower the resistance between these structures. Additionally, the backside top FET contact 502 may be reduced in its lateral dimension to increase the distance between it and the frontside bottom FET contact 504, thereby decreasing the chance of shorting between these structures.

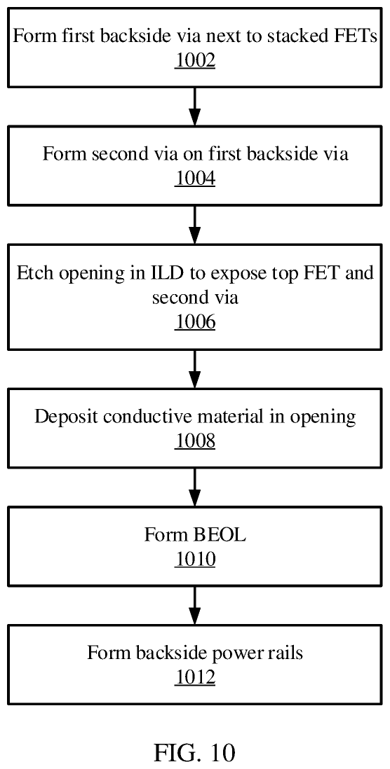

Referring now to FIG. 10, a method of forming multi-part backside contacts is shown. Starting from a stage when the stacked FETs have already been formed, including a bottom FET 112 and a top FET 114, block 1002 forms first backside via 202 by etching through an interlayer dielectric 116 to an underlying device layer 106 and then depositing conductive material. Other structures may be formed using the same process, such as bottom FET contacts 204.

Block 1004 forms second via 302 on the first backside via 202, for example by etching through the interlayer dielectric and depositing conductive material that contacts a top surface of the first backside via 202. This step may include formation of other second vias 302, for example to the bottom FET contacts 204.

Additional dielectric may be added to the interlayer dielectric 406, at which point block 1006 etches openings 402, 404, and 408 into the interlayer dielectric 406, exposing second vias 302. Formation of the openings may include multiple patterning and etching steps. For example, whereas formation of the opening 402 to expose the top FET 114 and associated second via 302 may include a single etch, formation of the opening 404 for frontside bottom FET contacts may include a first patterning to establish a lateral reach of the contact and a second patterning to reach down to the associated second via 302.

Block 1008 deposits conductive material in the opening, forming backside top FET contact 502. Additional contacts may be formed by this deposition, for example including the frontside bottom FET contact 504 and the frontside top FET contact 506. Excess conductive material may be removed by a CMP process that stops on the interlayer dielectric 406.

Additional processing steps may be performed at this stage to provide electrical connections to the respective contacts. For example, BEOL layers 606 may be formed on the front side of the device to provide electrical connections to the frontside contacts, while backside power distribution layers 902 may be formed on the back side of the device to provide electrical connections to the backside contacts.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of multi-part backside contacts for stacked transistors (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a top field effect transistor (FET);
a bottom FET;
a first conductive via in electrical connection with a first conductive interconnect beneath the bottom FET;
a second conductive via in electrical connection with the first conductive via; and
a backside top FET contact in electrical connection with the top FET and with a side surface of the second conductive via.

2. The semiconductor device of claim 1, wherein the first conductive via has a top surface at a height between a height of a bottom surface of the top FET and a height of a top surface of the bottom FET, relative to a back side of the device.

3. The semiconductor device of claim 1, wherein the first conductive via and the second conductive via are tapered, with each having a respective top surface that is wider than a respective bottom surface.

4. The semiconductor device of claim 1, further comprising a back-end-of-line (BEOL) layer, above the top FET, that includes a second conductive interconnect.

5. The semiconductor device of claim 4, further comprising:
a frontside bottom FET contact in electrical connection to the second conductive interconnect;
a third via in electrical connection to the frontside bottom FET contact; and
a bottom FET contact in electrical connection to the third via and to the bottom FET.

6. The semiconductor device of claim 1, wherein the second conductive via has a top surface with a height greater than a height of a top surface of the top FET, relative to a back side of the device.

7. A semiconductor device, comprising:
a first stacked pair of field effect transistors (FETs), including:
a first top FET;
a first bottom FET;
a first conductive via in electrical connection with a first conductive interconnect under the first bottom FET;
a second conductive via in electrical connection with the first conductive via; and
a backside top FET contact in electrical connection with the first top FET and with a side surface of the second conductive via; and
a second stacked pair of FETs, including:
a second top FET;
a second bottom FET;
a frontside bottom FET contact in electrical connection to a second conductive interconnect above the second top FET;
a third via in electrical connection to the frontside bottom FET contact; and
a bottom FET contact in electrical connection to the third via and to the second bottom FET.

8. The semiconductor device of claim 7, wherein the first conductive via has a top surface at a height between a height of a bottom surface of the first top FET and a height of a top surface of the first bottom FET, relative to a back side of the device.

9. The semiconductor device of claim 7, wherein the first conductive via and the second conductive via are tapered, with each having a respective top surface that is wider than a respective bottom surface.

10. The semiconductor device of claim 7, further comprising a back-end-of-line (BEOL) layer, above the top FET, that includes the second conductive interconnect.

11. The semiconductor device of claim 7, further comprising a buried power distribution layer, below the bottom FET, that includes the first conductive interconnect.

12. The semiconductor device of claim 7, wherein the second conductive via has a top surface with a height greater than a height of a top surface of the first top FET, relative to a back side of the device.

13. The semiconductor device of claim 7, wherein the first conductive via has a top surface with a height that is the same as a height of a top surface of the bottom FET contact, relative to a back side of the device.

14. A semiconductor device, comprising:
a buried power distribution layer that includes a first conductive interconnect;
a back-end-of-line (BEOL) layer that includes a second conductive interconnect;
a first stacked pair of field effect transistors (FETs) between the buried power distribution layer and the BEOL layer, including:
a first top FET;
a first bottom FET;
a first conductive via in electrical connection with the first conductive interconnect;
a second conductive via in electrical connection with the first conductive via; and
a backside top FET contact in electrical connection with the first top FET and with a side surface of the second conductive via; and
a second stacked pair of FETs between the buried power distribution layer and the BEOL layer, including:
a second top FET;
a second bottom FET;
a frontside bottom FET contact in electrical connection to the second conductive interconnect;
a third via in electrical connection to the frontside bottom FET contact; and
a bottom FET contact in electrical connection to the third via and to the second bottom FET.

15. The semiconductor device of claim 14, wherein the first conductive via has a top surface at a height between a height of the first top FET and a height of the first bottom FET.

16. The semiconductor device of claim 14, wherein the first conductive via and the second conductive via are tapered, with each having a respective top surface that is wider than a respective bottom surface.

17. The semiconductor device of claim 14, wherein the second conductive via has a top surface with a height greater than a height of a top surface of the first top FET.

18. The semiconductor device of claim 14, wherein the first conductive via has a top surface with a height that is the same as a height of a top surface of the bottom FET contact.

19. The semiconductor device of claim 14, further comprising a third stacked pair of FETs between the buried power distribution layer and the BEOL layer, including:
a third top FET;
a third bottom FET;
a frontside top FET contact in electrical connection between a third conductive interconnect in the BEOL layer and the third top FET; and
a backside bottom FET contact in an electrical connection between a fourth conductive interconnect in the buried power distribution layer and the third bottom FET.

20. The semiconductor device of claim 19, wherein the backside bottom FET contact is directly below the third bottom FET.
